(19) United States
(12) Patent Application Publication
(10) Pub. No.: US 2009/0066445 A1
(43) Pub. Date: Mar. 12, 2009

(54) Axial Dielectric Component Array And Method

(76) Inventors: Jeffrey D. Chereson, Erie, PA (US); Robert L. Ehrensberger, Erie, PA (US)

Correspondence Address: HODGSON RUSS LLP;THE GUARANTY BUILDING, 140 PEARL STREET, SUITE 100, BUFFALO, NY, 14202-4040, US

(21) Appl. No.: 12/116,776

(22) Filed: May 7, 2008

Related U.S. Application Data
(60) Provisional application No. 60/928,036, filed on May 7, 2007.

(51) Int. Cl. H03H 7/09

(52) U.S. Cl. 333/167

(57) ABSTRACT

An embodiment of the invention may be made in the form of an electromagnetic filter for use with a feed-through conductor. A dielectric component, for example a varistor or a chip capacitor, may be positioned proximate the feed-through conductor such that the dielectric component may filter a signal carried by the feed-though conductor. A first end of the dielectric component may be electrically connected to the feed-through conductor. The filter may also include a housing, a substrate, or both and a second end of the dielectric component may be electrically connected to such housing and/or substrate. The invention may also be embodied as a dielectric array, which may include one or more dielectric components arranged around the periphery of an orifice on a substrate. The orifice may be configured to allow a feed-through conductor to pass therethrough, and a first end of one or more dielectric components may be capable of being electrically connected to such feed-through conductor.

### CROSS-REFERENCE TO RELATED APPLICATION

This application claims the benefit of priority to U.S. provisional patent application Ser. No. 60/928,036, filed on May 7, 2007, now pending.

### FIELD OF THE INVENTION

The present invention relates to the use of dielectrics to provide signal conditioning.

### BACKGROUND OF THE INVENTION

In the prior art, it is known to use coaxial dielectric components to condition a signal being carried by a feed-through conductor. Such coaxial arrangements are expensive to manufacture, and do not readily allow for variations in the dielectric response to match differing needs. For example, if one customer desires a different response from the dielectric, it is often expensive to make the change, and may take an undesired amount of time.

To solve this problem, the prior art includes the use of two or more chip-type dielectrics, each dielectric being mounted to a substrate near the feed-through conductor. Chip-type dielectrics are typically packaged as a rectangular parallelepiped. For a particular outer dimension of the parallelepiped package, the electrical characteristics may vary by altering the components inside the parallelepiped package. For example, the materials of one capacitor in a particularly sized parallelepiped package may be different from the materials of another capacitor using the same sized parallelepiped package, and thus the electrical characteristics from capacitor to capacitor may vary even thought the size of the package does not. Consequently, the footprint of the dielectric on the substrate may be maintained even though the dielectric value (e.g. capacitance) may be changed. In this manner, the size of a signal conditioning circuit may remain the same but the effect of the signal conditioning circuit may vary. In this manner, the manufacturing process may remain substantially the same, even though the product behaves differently in use.

When chip-type dielectrics are used around a feed-through conductor, a first terminal of each dielectric is electrically connected to the feed-through conductor and a second terminal of each dielectric is usually electrically connected to ground or a circuit so that unwanted signals being carried by the feed-through conductor are dissipated by the dielectric component. In the prior art, the rectangular-packaged chip-type dielectrics are arranged around the feed-through conductor so that the shortest dimension is substantially parallel with the feed-through conductor. The resulting arrangement places the longest dimension of the capacitor to be substantially parallel with the substrate surface. As an example of the prior art, U.S. Pat. No. 5,959,829 discloses such an arrangement in FIGS. 1, 3, 5, 7 and 9. Consequently, the flow of electrons within these chip-type dielectrics is primarily either radially away from or radially toward the feed-through conductor. We have found that such an arrangement of chip-type dielectrics does not fully utilize the chip-type dielectric's ability to condition the signal being carried by the feed-through conductor.

### BRIEF SUMMARY OF THE INVENTION

In the present invention, the chip-type dielectric components are configured so that the primary dimension of the dielectric components is substantially parallel to the feed-through conductor. An advantage that may be realized from orienting the chip-type dielectric components in this manner is that field cancellation occurring between the current flow within the dielectric and an opposing current flow in the feed-through conductor may be used to afford more complete signal conditioning, because the field generated by the feed-through conductor is in close proximity to the cancelling field of the chip capacitor. In the prior art, this effect is not present when the capacitor is connected by a trace in the circuit board, and therefore far from the feed-through conductor, and this effect is also not present when the longest dimension of the capacitor is oriented perpendicular to the feed-through conductor. This advantage may be achieved to a greater extent by stacking dielectric devices in a series arrangement to form a dielectric component. In addition, by stacking chip-type dielectric devices, the impedance of the system may be tuned. In this manner, standard-sized chip-type capacitors may be used to achieve improved performance.

An embodiment of the invention may be made in the form of an electromagnetic filter, which may include a feed-through conductor. A chip-type dielectric component, for example a chip varistor or a chip capacitor, may be positioned proximate the feed-through conductor such that the dielectric component may filter a signal carried by the feed-though conductor. A first end of the dielectric component may be electrically connected to the feed-through conductor.

More than one dielectric component may be used to surround the periphery of the feed-through conductor in order to approximate the performance of a coaxial capacitor. In addition, using more than one dielectric component may provide a measure of safety in the event one of the dielectric components develops a short—that is to say if one dielectric component fails, the other dielectric components may continue to function. Additionally, the dielectric component may be made from more than one dielectric device in order to improve design flexibility and add failsafe capabilities. For example, a dielectric component may be many chip-type capacitors connected to each other in series. The filter may also include a housing, a substrate, or both, and a second end of the dielectric component may be electrically connected to such housing and/or substrate.

The invention may be used in systems having more than one feed-through conductor. Additional dielectric components may be similarly oriented and similarly connected in relation to the second feed-through conductor. In such an embodiment, a coupling capacitor may be added such that one terminal of the coupling capacitor is electrically connected to one of the feed-through conductors, and another of the coupling capacitor's terminals is electrically connected to another of the feed-through conductors.

The invention may also be embodied as a dielectric array, which may include one or more dielectric components arranged around the periphery of an orifice located on a substrate. The orifice may be configured to allow a feed-through conductor to pass therethrough, and a first end of one or more dielectric components may be capable of being electrically connected to such a feed-through conductor.

### DESCRIPTION OF THE DRAWINGS

For a fuller understanding of the nature and objects of the invention, reference should be made to the following detailed description taken in conjunction with the accompanying drawings, in which:

FIG. 1 is a perspective view of a device according to the invention in which part of the device has been cut away to show a section of the interior of the device;

FIG. 1a is a top view of the device depicted in FIG. 1 showing how the insulators and dielectric components may alternate with each other;

FIG. 2 is a perspective view of a device according to another embodiment of the invention having dielectric devices connected in series, in which part of the device has been cut away to show a section of the interior of the device;

FIG. 2a is a perspective view of the device depicted in FIG. 2 disposed on a substrate, part of which has been cut away in a manner similar to that of the device itself,

FIG. 3 is a perspective view of a device according to another embodiment of the invention which has two feed-through conductors;

FIG. 4 is a top view of the device depicted in FIG. 3;

FIG. 5 is a perspective view of a device according another embodiment of the invention, which has two feed-through conductors and a coupling dielectric component;

FIG. 6 is a top view of the device depicted in FIG. 5;

FIG. 7 is a perspective view of a device according to another embodiment of the invention having a substrate;

FIG. 8 is a perspective view of a device according to another embodiment of the invention having a substrate and having dielectric device electrically connected in series, in which part of the device has been cut away to show a section of the interior of the device; and

FIG. 9 is a flow chart of a method according to the invention.

### DETAILED DESCRIPTION OF THE INVENTION

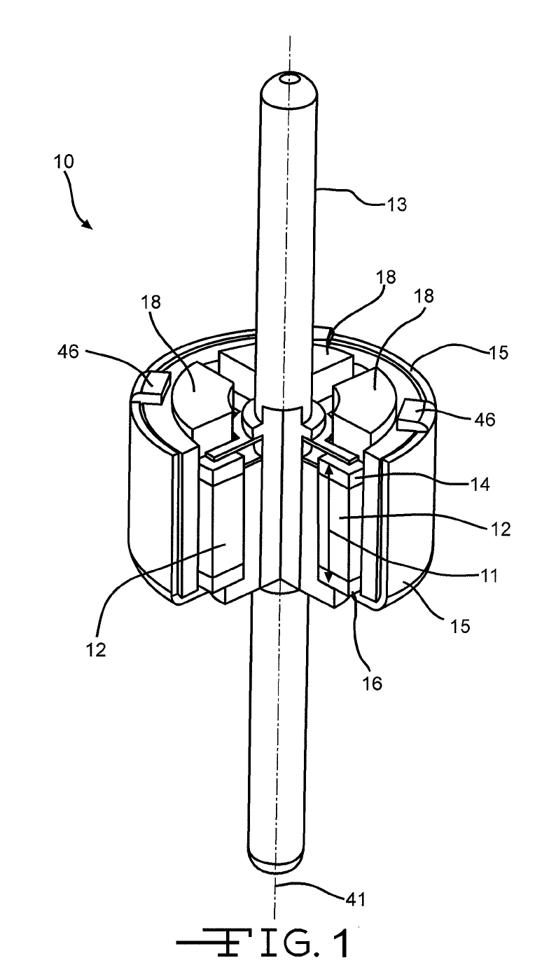

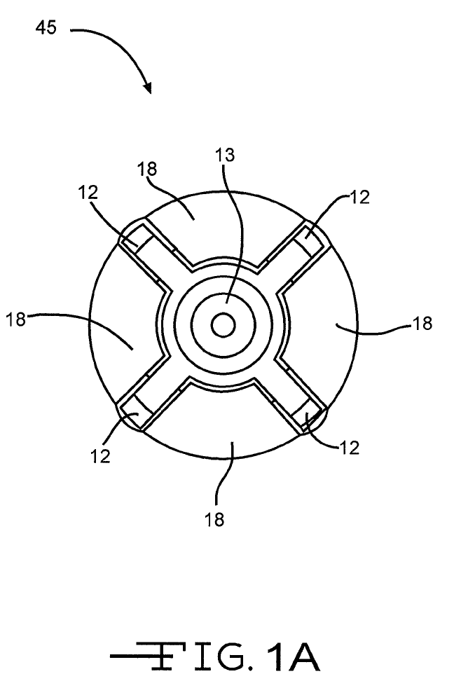

An embodiment of the invention may be made in the form of an electromagnetic filter 10. FIG. 1 is a perspective view of such a filter 10, which has been partially sectioned to show certain features. The filter 10 may include a feed-through conductor 13. A dielectric component 12, having a first end 14 and a second end 16, may be proximate the feed-through conductor 13. The dielectric component 12 may be, for example, a varistor, a chip capacitor, or the like, positioned to filter a signal carried by the feed-through conductor 13. The first end 14 of the dielectric component 12 may be electrically connected to the feed-through conductor 13. The electrical connection at the first end 14 of the dielectric component 12 may be made by, for example, soldering, use of a conductive epoxy, use of a spring compressed between the dielectric component 12 and the feed-through conductor 13, and/or by forcing the dielectric component 12 against the feed-through conductor 13 by a spring applying pressure to the second end of the dielectric component 12.

The dielectric component 12 may have dimensions, such as a length dimension, a width dimension and a depth dimension. Herein, reference is made to a “primary dimension”, which is a dimension of the dielectric component 12 for which there is no other dimension that is longer than the primary dimension. In some embodiments of the invention, there will be one dimension of the dielectric component 12 that is the longest dimension, and that will be the primary dimension. In other embodiments of the invention, there will be two or more dimensions that are of equal length and for which there is no other dimension that is longer, and in that situation any of these equal length dimensions may be selected as the primary dimension.

The dielectric component 12 may be oriented such that the primary dimension is substantially parallel to the feed-through conductor 13. For example, if the feed-through conductor 13 is cylindrical, the primary dimension of the dielectric component 12 may be oriented to be substantially parallel to the center line of the feed-through conductor 13.

In FIG. 1, the dielectric component 12 is depicted as a rectangular parallelepiped package having three dimensions of different lengths. It can be seen that the dielectric is oriented such that the primary dimension 11 of the dielectric component 12 is substantially parallel to the feed-through conductor 13. FIG. 1 also shows that a first end 14 of the dielectric component 12 may be electrically connected to the feed-through conductor 13.

More than one dielectric component 12 may be used in the filter 10. The dielectric components 12 may be similarly positioned with respect to the feed-through conductor 13 in that they may be proximate to the feed-through conductor 13. Also, the dielectric components 12 may be oriented similarly with respect to the feed-through conductor 13 in that each dielectric component 12 may be oriented so that the primary dimension of each dielectric component 12 is substantially parallel to the feed-through conductor 13.

When more than one dielectric component 12 is used, the dielectric components 12 may be spaced apart from each other so that they are positioned around the feed-through conductor 13. The dielectric components 12 may positioned at substantially the same lengthwise position of the feed-through conductor 13 so that the electromagnetic effect on the feed-through conductor 13 caused by the dielectric components 12 occurs at substantially the same lengthwise location. In this manner, there will be space between adjacent ones of the dielectric components 12. The spaces between adjacent dielectric components 12 may be substantially equal so that the dielectric components 12 are distributed substantially evenly around the periphery of the feed-through conductor 13. In this manner, the dielectric components 12 may provide higher radio-frequency (“RF”) (insertion loss) performance than conventional chip capacitor filter designs. The arrangement of the dielectric components may allow the filter 10 to approach the performance of a coaxial filter, without using a coaxial filter.

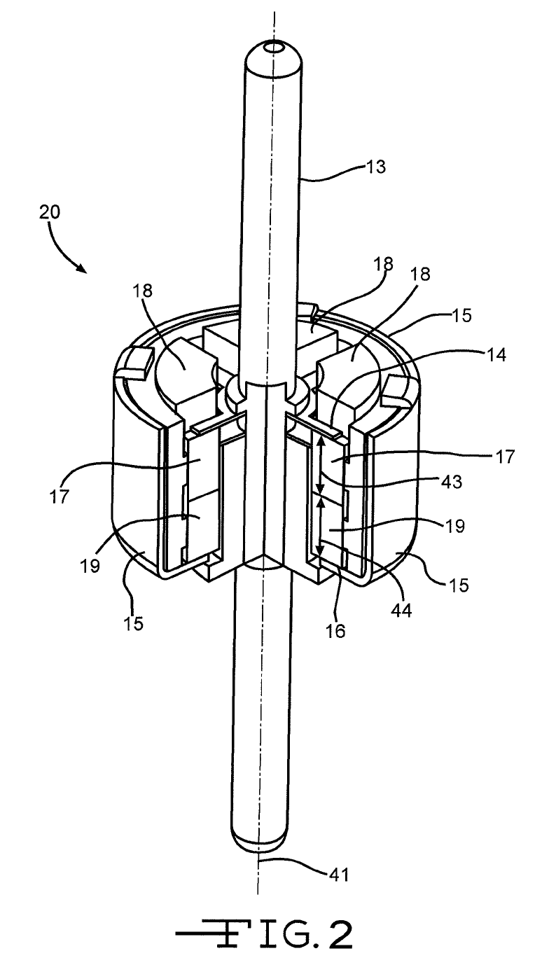

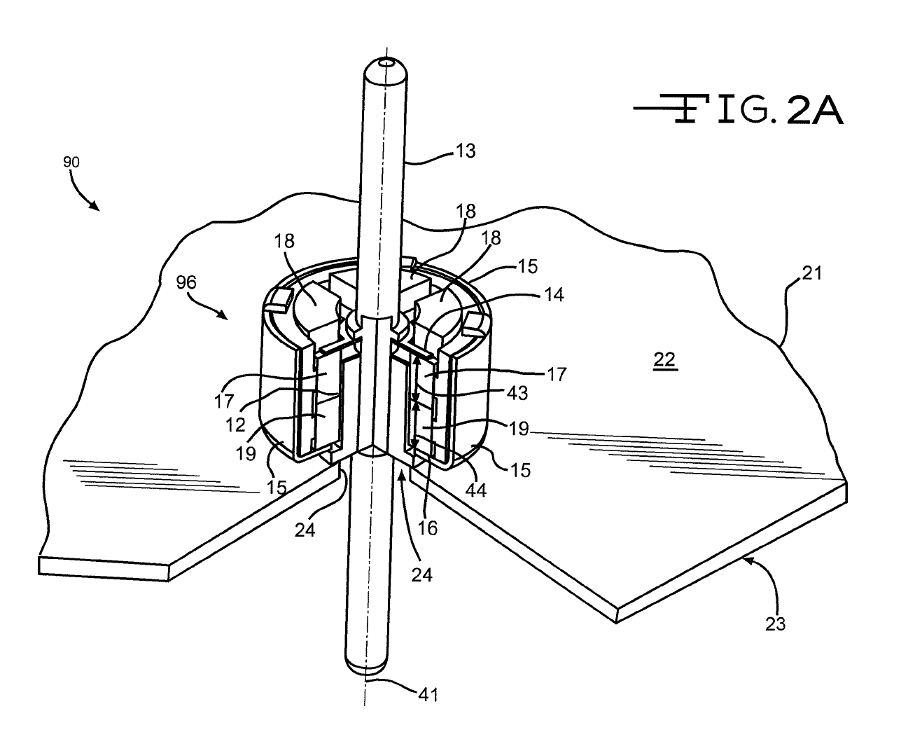

FIG. 2 depicts a device 20 that is in keeping with the invention. In this device 20, the dielectric components 12 each have more than one dielectric device 17, 19. In the device 20, the dielectric devices 17, 19 are capacitors connected in series so that the second end of the first capacitor 17 is electrically connected to the first end of the second capacitor 19. The dielectric devices 17, 19 may be oriented such that the primary dimension 43, 44 of each dielectric device 17, 19 is substantially parallel to the feed-through conductor 13. This arrangement of the dielectric components 12 also allows a designer to tune the circuit using dielectric devices 17, 19 in a series pattern as well as creates a possible failsafe by having redundant dielectric devices 17, 19 if one of the dielectric devices 17, 19 should fail. The space around the periphery of the feed-through conductor 13 that is not occupied by the dielectric components 13 may be occupied by insulators 18. For example, the embodiment in FIG. 1a depicts insulators 18 disposed in the circumferential spaces between the dielectric components 12. Such an arrangement results in a dielectric component array 45 positioned at a lengthwise location of the feed-though conductor 13, wherein the array is comprised of circumferentially distributed and alternating dielectric components 12 and insulators 18.

The device 10 may have a housing 15, which may surround the dielectric component(s) 12 and the insulators 18, if any. The housing 15 may be present to provide protection to the electromagnetic filter 10, for example protection from stray mechanical or electrical contact with other devices. The second ends 16 of the dielectric components 12 may be electrically connected to the housing 15. The housing 15 may be fashioned to permit the dielectric components 12 and insulators 18 to be assembled as an integral unit. The housing 15 may include tabs 46, which may later be used to attach the housing 15 to a substrate 47, such as a printed circuit board, as shown in FIG. 2a. By using such a housing 15, the dielectric array may be preassembled with the housing, and later the dielectric array and housing may be used as an integral unit during production of a finished product that may include a substrate and/or feed-through conductor.

Another embodiment of a device 90 according to the invention is depicted in FIG. 2a. Here, the filter 96 is mounted on a substrate 21 having a first side 22. The substrate 21 may be, for example, a printed circuit board. The substrate 21 may have a second side 23 and a feed-through surface 24. The feed-through surface 24 may define an orifice 25 extending from the first side 22 to the second side 23. The feed-through conductor 13 may extend through the orifice 25. The second end 16 of the dielectric component 12 may be electrically connected to the substrate 21, or to an electric circuit on the substrate 21.

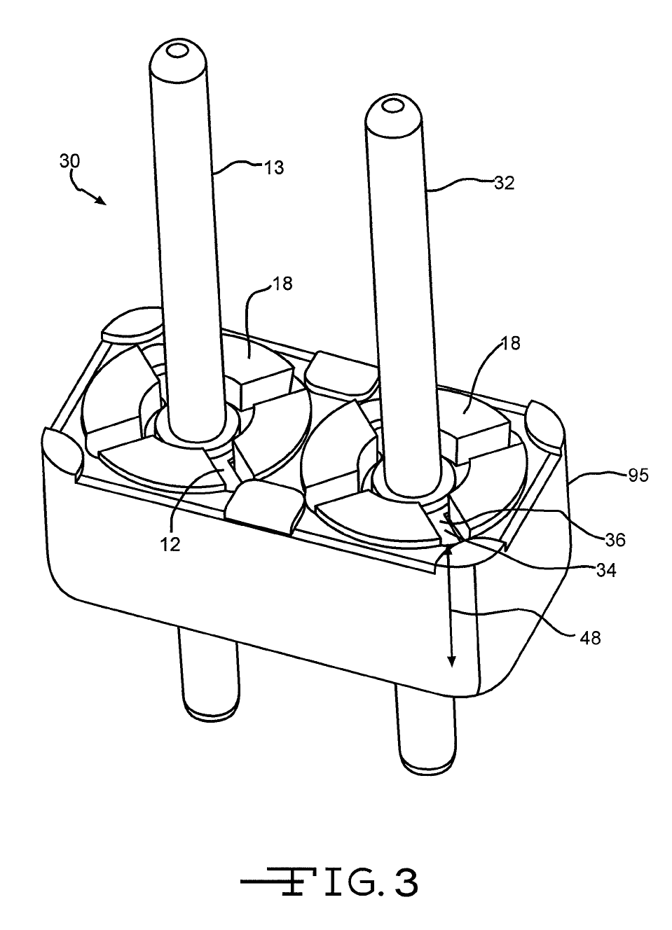

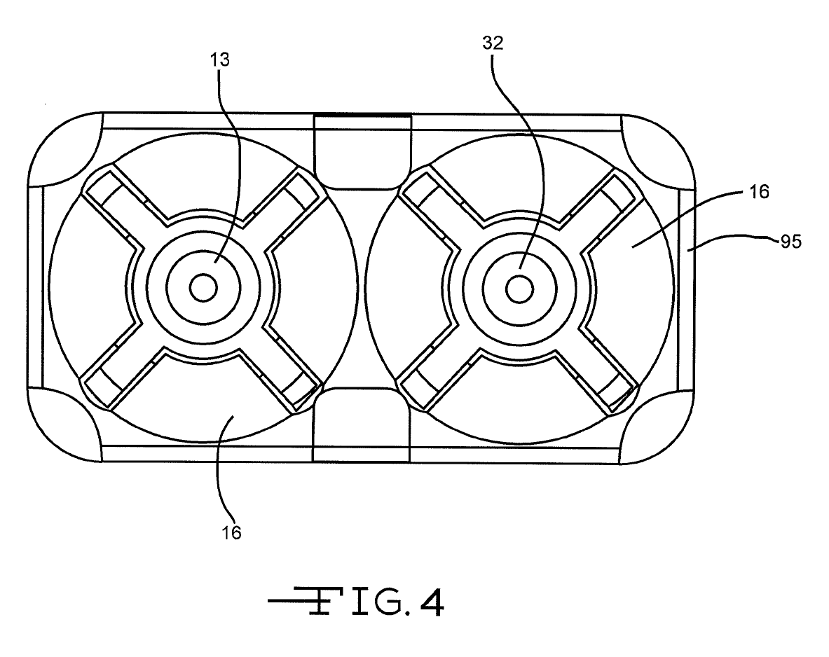

FIGS. 3 and 4 show a device 30 that is in keeping with the invention. The device 30 has a second feed-through conductor 32 and a second dielectric component 34. The second feed-through conductor 32 may be substantially parallel to the first feed-through conductor 13. The second dielectric component 34 may be proximate to the second feed-through conductor 32 so that the second dielectric component 34 may filter a signal present in the second feed-through conductor 32, and the primary dimension 48 of the second feed-through conductor 32 may be oriented such that it is substantially parallel to the second feed-through conductor 32. The first end 36 of the second dielectric component 34 may be electrically connected to the second feed-through conductor 32. The device 30 may include a housing 95.

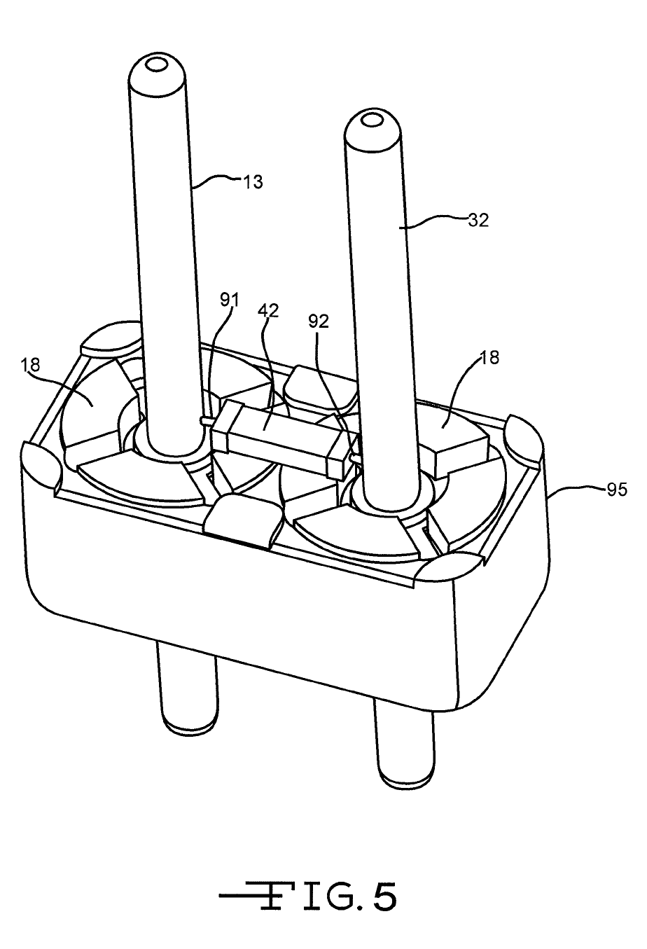

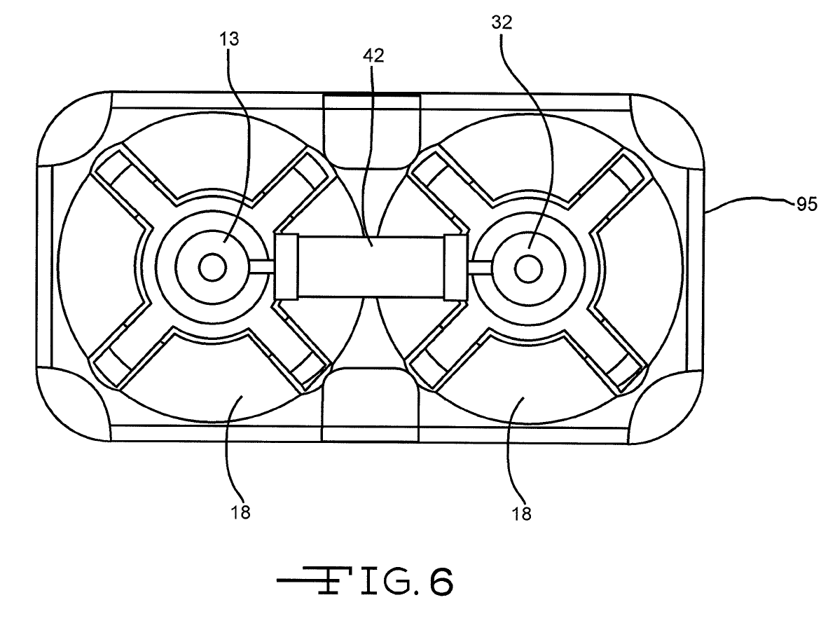

FIGS. 5 and 6 show an embodiment similar to that of FIGS. 3 and 4 but further comprising a coupling dielectric component 42. A first end 91 of the coupling dielectric component 42 may be electrically connected to a first feed-through conductor 13 and a second end 92 of the coupling dielectric component 42 may be electrically connected to a second feed-through conductor 32. In this manner, additional electromagnetic filtering may be accomplished.

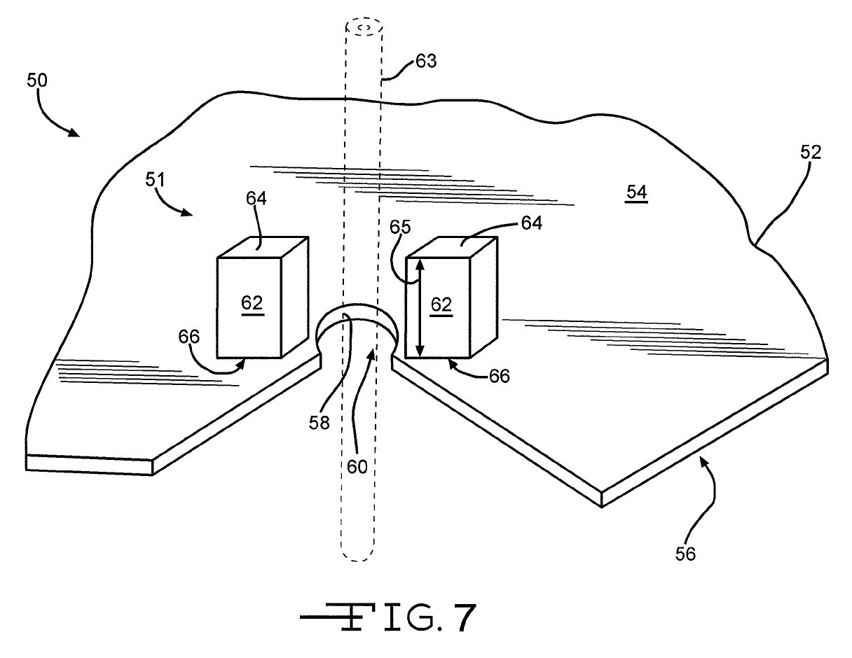

In another embodiment of the present invention, depicted in FIG. 7, the device 50 may be a dielectric array 51 mounted to a substrate 52. The substrate 52 is shown having a first side 54 and a second side 56. A feed-through surface 58 extends from the first side 54 to the second side 56, and defines an orifice 60. During manufacture of the substrate 52, the feed-through surface 58 may be coated with an electrically conductive material, such as copper, to provide a metalized surface. The orifice 60 may be sized to receive a feed-through conductor. A dielectric component 62, having a first end 64 and a second end 66, may be positioned on the first side 54 of the substrate 52 and proximate to the orifice 60. The dielectric component 62 may be oriented such that the primary dimension 65 of the dielectric component 62 is substantially perpendicular relative to the substantially planar surface of the first side 54. The first end 64 of the dielectric component 62 may be capable of being electrically connected to the metalized surface of the feed-through surface 58, which may later be electrically connected to a feed-through conductor 63 passing through the orifice 60. The second end 66 of the dielectric component 62 may be capable of being electrically connected to an object, such as, for example, the substrate 52 or a circuit on the substrate 52. The substrate 52 and the feed-through conductor 63 may have different electric potentials.

More than one dielectric component 62 may be used in the array. The dielectric components 62 may be similarly oriented with respect to the orifice 52 so that each dielectric component 62 has a primary dimension 65 extending substantially perpendicular to the substantially planar first side 54. The dielectric components 62 may be spaced apart from each other around the periphery of the orifice 52. The spacing separating the dielectric components 62 may be such that they are substantially evenly distributed around the periphery of orifice 62.

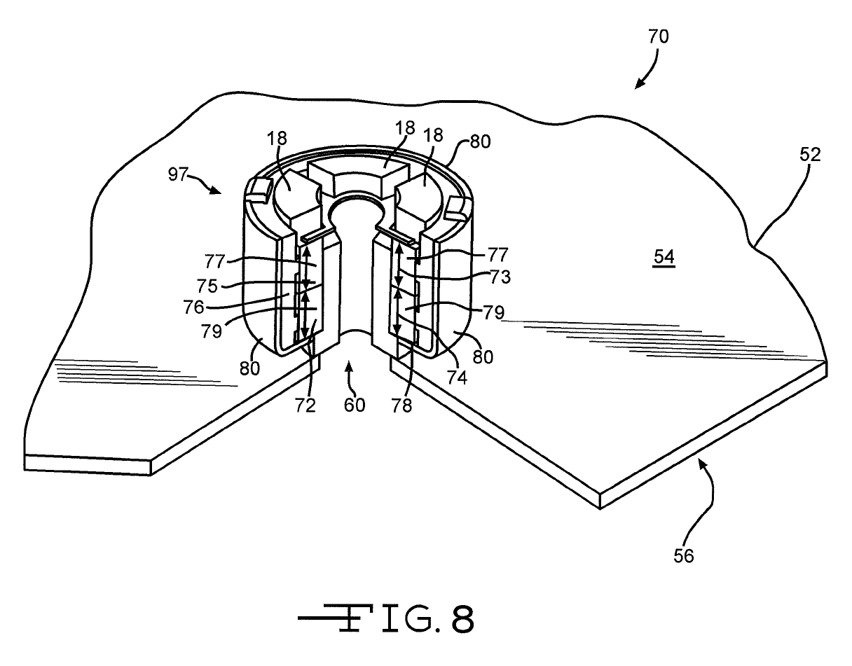

FIG. 8 depicts another embodiment of the invention in the form of a device 70 in which the dielectric components 72 are comprised of more than one dielectric device—in this situation two dielectric devices 77, 79. The dielectric devices 77, 79 may be capacitors, and these may be electrically connected in series so that a second end 75 of the first dielectric device 77 is electrically connected to a first end 76 of the second dielectric device 79. The dielectric devices 77, 79 may be oriented such that the primary dimension 73, 74 of each dielectric device 77, 79 is substantially parallel to the feed-through conductor (not shown).

The space around the periphery of the orifice 60 that is not occupied by the dielectric components 62, 72 may be occupied by insulators 18. For example, the embodiment in FIG. 8 depicts insulators 18 disposed in the circumferential spaces between the dielectric components 72. Such an arrangement results in a dielectric component array 97 positioned on the first surface 54 of the substrate 52, wherein the array is comprised of circumferentially distributed and alternating dielectric components 72 and insulators 18. The device 50, 70 may have a housing 80, which may surround the dielectric component 62, 72 and the insulators 18, if any. The second end 66, 78 of the dielectric component 62, 72 may be electrically connected to the housing 80.

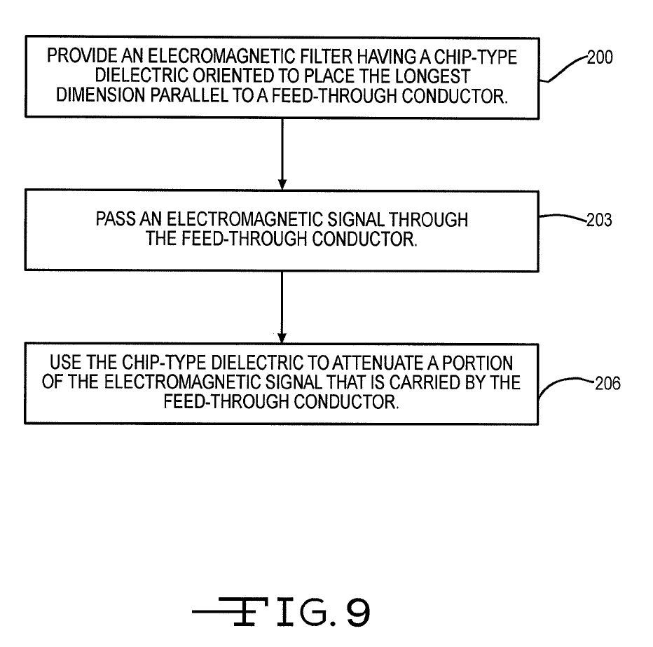

Having described systems and devices according to the invention, it may be apparent that the invention may include a method of conditioning a signal. FIG. 9 depicts one such method. In that such method, an electromagnetic filter may be provided 200. The filter may have one or more chip-type dielectrics oriented so that the longest dimensions of the chip-type dielectrics are parallel to a feed-through conductor, and so that the chip-type dielectrics are proximate to the feed-through conductor. The proximity of the chip-type dielectrics may be sufficient to allow the magnetic field of the chip-type dielectric to affect the magnetic field of the feed-through conductor. A first end of each chip-type dielectric may be electrically connected via a conductor to the feed-through conductor. A second end of each chip-type dielectric may be electrically connected so that the chip-type dielectric can function to attenuate one or more portions of a signal carried by the feed-through conductor. An electromagnetic signal may be passed 203 through the feed-through conductor, and a portion of the electromagnetic signal may be attenuated 206 by the chip-type dielectric component.

U.S. provisional patent application No. 60/928,036, filed on May 7, 2007, discloses additional details about the invention and additional embodiments of the invention. The disclosure of that patent application is incorporated by this reference.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

What is claimed is:

1. A electromagnetic filter, comprising:
a feed-through conductor;
a chip-type dielectric component having a first end and a second end, wherein:
(a) the dielectric component is proximate the feed-through conductor;
(b) a primary dimension of the dielectric component is oriented substantially parallel to the feed-through conductor; and
(c) the first end of the dielectric component is electrically connected to the feed-through conductor.

2. The electromagnetic filter of claim 1, further comprising at least one additional chip-type dielectric component having a first end and a second end, wherein:
(a) each additional dielectric component is proximate the feed-through conductor and at substantially a same lengthwise position with respect to the feed-through conductor;
(b) a primary dimension of each additional dielectric component is oriented substantially parallel to the feed-through conductor; and
(c) the first end of each additional dielectric component is electrically connected to the feed-through conductor.

3. The electromagnetic filter of claim 2, wherein periphery spaces around the feed-through conductor and between the dielectric components are substantially equal in size.

4. The electromagnetic filter of claim 2, further comprising at least one insulator disposed in periphery space around the feed-through conductor between two of the dielectric components.

5. The electromagnetic filter of claim 2, wherein the dielectric component includes at least two dielectric devices electrically connected in series to each other.

6. The electromagnetic filter of claim 1, further comprising a housing surrounding the dielectric component.

7. The electromagnetic filter of claim 6, wherein the second end of the dielectric component is electrically connected to the housing.

8. The electromagnetic filter of claim 1, further comprising a substrate having a first side, a second side, and a feed-through surface, the feed-through surface defining an orifice extending from the first side to the second side, and wherein the feed-through conductor extends through the orifice.

9. The electromagnetic filter of claim 8, wherein the second end of the dielectric component is electrically connected to the substrate.

10. The electromagnetic filter of claim 1, wherein the dielectric component includes at least two dielectric devices electrically connected in series to each other.

11. The electromagnetic filter of claim 1, further comprising:
a second feed-through conductor, wherein the second feed-through conductor is oriented such that the second feed-through conductor is substantially parallel with the first feed-through conductor;
a second chip-type dielectric component having a first end and a second end, wherein:
(a) the second dielectric component is proximate to the second feed-through conductor;
(b) a primary dimension of the second dielectric component is oriented substantially parallel to the second feed-through conductor; and
(c) the first end of the second dielectric component is electrically connected to the second feed-through conductor.

12. The electromagnetic filter of claim 11, further comprising a coupling dielectric component having a first end and a second end, wherein the first end is electrically connected to the first feed-through conductor and the second end is electrically connected to the second feed-through conductor.

13. A dielectric array, comprising:
a substrate having a first side, a second side, and a feed-through surface, the feed-through surface defining an orifice extending from the first side to the second side;
a chip-type dielectric component having a first end and a second end, wherein:
(a) the dielectric component is disposed on the first side of the substrate, proximate the orifice;
(b) a primary dimension of the dielectric component is oriented substantially perpendicular to the first side of the substrate; and
(c) the first end of the dielectric component is capable of being electrically connected to a feed-through conductor.

14. The dielectric array of claim 13, further comprising at least one additional chip-type dielectric component having a first end and a second end, wherein:
(a) each additional dielectric component is disposed on the first side of the substrate, proximate the orifice;
(b) a primary dimension of each additional dielectric component is oriented substantially perpendicular to the first side of the substrate; and
(c) the first end of each additional dielectric component is capable of being electrically connected to a feed-through conductor.

15. The dielectric array of claim 14, wherein periphery spaces between the dielectric components are substantially equal in size.

16. The dielectric array of claim 14, further comprising at least one insulator disposed on the first side of the substrate in periphery space between two of the dielectric components.

17. The dielectric array of claim 13, further comprising a housing wherein the housing surrounds the dielectric component.

18. The dielectric array of claim 17, wherein the second end of the dielectric component is electrically connected to the housing.

19. The dielectric array of claim 13, wherein the dielectric component includes at least two dielectric devices electrically connected in series to each other.

20. A method of signal conditioning in a conductor, comprising the steps of:
providing an electromagnetic filter, the electromagnetic filter comprising
(a) a feed-through conductor;
(b) a chip-type dielectric component having a first end and a second end, wherein:
(i) the dielectric component is proximate the feed-through conductor;
(ii) a primary dimension of the dielectric component is oriented substantially parallel to the feed-through conductor;
(iii) the first end of the dielectric component is electrically connected to the feed-through conductor; and
passing an electromagnetic signal through the feed-through conductor;
attenuating a portion of the electromagnetic signal using the chip-type dielectric component.
